(19) United States
(12) Patent Application Publication
(10) Pub. No.: US 2007/0077671 A1
(43) Pub. Date: Apr. 5, 2007

(54) In-situ substrate imaging

(75) Inventors: Jeffrey Drue David, San Jose, CA (US); Nils Johansson, Los Gatos, CA (US); Boguslaw A. Swedek, Cupertino, CA (US)

Correspondence Address: FISH & RICHARDSON P.C., P.O. BOX 1022, MINNEAPOLIS, MN, 55440-1022, US

(73) Assignee: Applied Materials, Santa Clara, CA (US)

(21) Appl. No.: 11/242,715

(22) Filed: Oct. 3, 2005

(51) Int. Cl. H01L 21/00

(52) U.S. Cl. 438/29; 438/65

(57) ABSTRACT

Methods and products, including computer program products, for endpoint determination. An image of a portion of a substrate is captured in-situ, where the image includes optical information that depends on a thickness of a substrate layer. The image is examined to find a location on the substrate, and a process endpoint is determined using a portion of the optical information that corresponds to the location.

### BACKGROUND

This invention relates to chemical mechanical polishing of substrates.

An integrated circuit typically is formed on a substrate by the sequential deposition of conductive, semiconductive, or insulative layers on a silicon substrate. One fabrication step involves depositing a filler layer over a non-planar surface, and planarizing the filler layer until the non-planar surface is exposed. By way of example, a metal filler layer can be deposited on a patterned oxide layer to fill the trenches or holes in the oxide layer. The filler layer is then polished until the raised pattern of the oxide layer is exposed. After planarization, the portions of the metal layer remaining in the trenches provide circuits on the substrate. In addition, planarization is needed to planarize the substrate surface for photolithography.

Chemical mechanical polishing (CMP) is one accepted method of planarization. This planarization method typically requires that the substrate be mounted on a carrier or polishing head. The exposed surface of the substrate is placed against a polishing surface such as a rotating polishing disk pad or belt pad. The polishing surface can be either a “standard” pad or a fixed-abrasive pad. A standard pad has a durable roughened surface, whereas a fixed-abrasive pad has abrasive particles held in a containment medium. The carrier head provides a controllable load on the substrate to push it against the polishing pad. A polishing slurry including at least one chemically-reactive agent, and abrasive particles if a standard pad is used, is supplied to the polishing surface.

One problem in CMP is determining whether the polishing process is complete, i.e., whether a substrate layer has been planarized to a desired flatness or thickness, when a desired amount of material has been removed, or when an underlying layer has been exposed. Variations in the initial thickness of the substrate layer, the slurry composition, the polishing pad condition, the relative speed between the polishing pad and the substrate, and the load on the substrate can cause variations in the material removal rate. These variations cause variations in the time needed to reach the polishing endpoint. Therefore, the polishing endpoint cannot be determined merely as a function of polishing time.

One way to determine the polishing endpoint is to remove the substrate from the polishing surface and examine it. For example, the substrate can be transferred to a metrology station where the thickness of a substrate layer is measured (e.g., with a profilometer or a resistivity measurement). If the desired specifications are not met, the substrate is reloaded into the CMP apparatus for further processing. This is a time-consuming procedure that reduces the throughput of the CMP apparatus. Alternatively, the examination might reveal that an excessive amount of material has been removed, rendering the substrate unusable.

More recently, in-situ monitoring of the substrate has been performed (e.g., with capacitance sensors) in order to detect the polishing endpoint. Other proposed endpoint detection techniques have involved measurements of friction, motor current, slurry chemistry, acoustics, conductivity, and induced eddy currents.

### SUMMARY

In one aspect, the invention features a method and a computer program product that capture an image of a portion of a substrate in-situ, where the image includes optical information that depends on a thickness of a substrate layer. The image is examined to find a location on the substrate, and a process endpoint is determined using a portion of the optical information that corresponds to the location.

Particular implementations can include one or more of the following features. Finding the location can include at least one of applying a pattern-recognition algorithm to the image, sharpening the image, and orienting the image. Orienting the image can include calculating standard deviations of averaged intensity values in the image. Determining a process endpoint using a portion of the optical information can include at least one of analyzing a spectrum of the image, using interferometry, and averaging a plurality of thicknesses at multiple locations in the image. The thickness of the substrate layer at the location can be obtained in-situ using the portion of the optical information that corresponds to the location, and the obtained thickness can be used to determine the process endpoint. The steps of capturing an image, finding a location, and obtaining the thickness can be repeated to monitor a change in thickness over time.

The substrate can include a plurality of dies, finding the location can include finding the location relative to a first die in the plurality of dies, and successive thicknesses can be obtained from a same location in different dies in the plurality of dies. An area of the portion of the substrate captured in the image can be greater than 4 mm². An additional image of the portion of the substrate can be captured, where the additional image can include additional optical information that depends on the thickness of the substrate layer, and determining the process endpoint can include determining the process endpoint using the additional optical information. The optical information that depends on the thickness of the substrate layer can include optical information centered at a first wavelength and the additional optical information that depends on the thickness of the substrate layer can include optical information centered at a second wavelength, where the first wavelength is different from the second wavelength.

An imaging window through which the image is captured can be cleaned. A polishing parameter can be adjusted using the optical information, where the polishing parameter affects a rate at which the substrate is polished. The substrate can include a plurality of dies, and the portion of the substrate included in the image can include substantially an entire die in the plurality of dies. A sequence of images of the substrate can be captured in-situ, where at least some of the sequence of images can include images of different dies in the plurality of dies. A common location in the different dies can be found in the images of the different dies, where determining the process endpoint using a portion of the optical information can include using optical information that corresponds to the common location in the different dies.

Implementations of the invention can realize one or more of the following advantages. An image of a substrate can be captured in-situ to allow an endpoint determination during polishing. Image enhancement and pattern recognition can allow the location of a specific feature of interest on the substrate to be determined accurately. A polishing endpoint can be determined accurately in-situ based on a thickness of a substrate layer at the feature. Multiple wavelengths in the image can be used to locate and determine the thickness at many types of features.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a schematic exploded perspective view of a chemical mechanical polishing apparatus.

FIG. 2 is a cross-sectional view of a polishing station.

FIG. 3 is a flowchart of a process for determining a polishing endpoint.

FIG. 4 is an image of a substrate.

FIG. 5 is a processed version of the image from FIG. 3

FIG. 6 is an image of a substrate.

FIG. 7 is a set of graphs of image intensity.

Like reference symbols in the various drawings indicate like elements.

### DETAILED DESCRIPTION

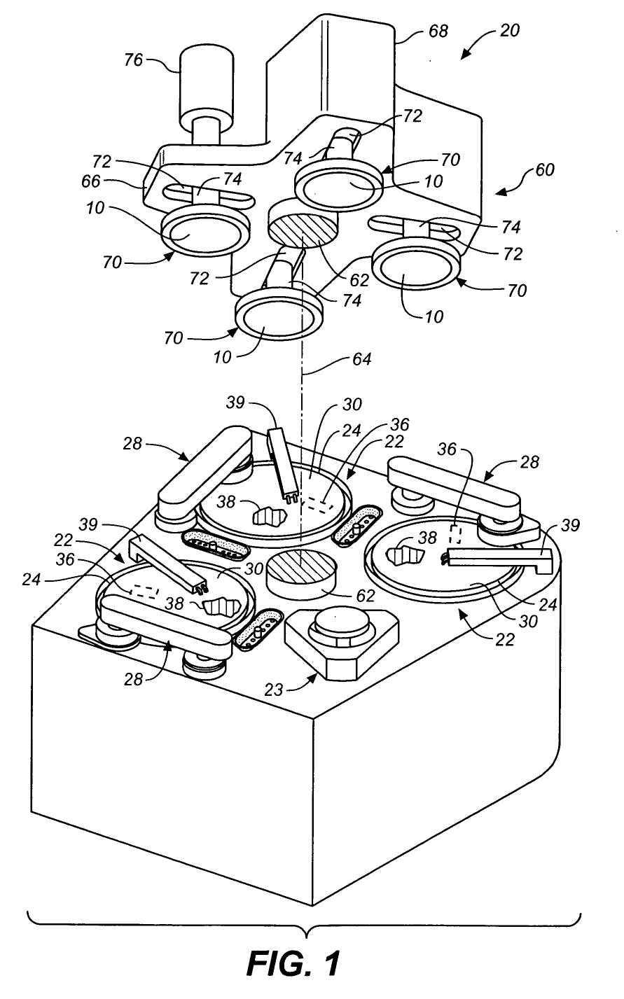

FIG. 1 shows a chemical mechanical polishing apparatus 20 that can polish one or more substrates 10. Polishing apparatus 20 includes a series of polishing stations 22 and a transfer station 23. Transfer station 23 transfers the substrates between carrier heads 70 and a loading apparatus.

Each polishing station includes a rotatable platen 24 on which is placed a polishing pad 30. The first and second stations can include a two-layer polishing pad with a hard durable outer surface or a fixed-abrasive pad with embedded abrasive particles. The final polishing station can include a relatively soft pad. Each polishing station can also include a pad conditioner apparatus 28 to maintain the condition of the polishing pad so that it will effectively polish substrates.

A rotatable multi-head carousel 60 supports four carrier heads 70. The carousel is rotated by a central post 62 about a carousel axis 64 by a carousel motor assembly (not shown) to orbit the carrier head systems and the substrates attached thereto between polishing stations 22 and transfer station 23. Three of the carrier head systems receive and hold substrates, and polish them by pressing them against the polishing pads. Meanwhile, one of the carrier head systems receives a substrate from and delivers a substrate to transfer station 23.

Each carrier head 70 is connected by a carrier drive shaft 74 to a carrier head rotation motor 76 (shown by the removal of one quarter of cover 68) so that each carrier head can independently rotate about it own axis. In addition, each carrier head 70 independently laterally oscillates in a radial slot 72 formed in carousel support plate 66. A description of a suitable carrier head 70 can be found in U.S. Pat. No. 6,422,927, entitled “Carrier head with controllable pressure and loading area for chemical mechanical polishing,” the entire disclosure of which is incorporated by reference.

A slurry 38 containing a reactive agent (e.g., deionized water for oxide polishing) and a chemically-reactive catalyzer (e.g., potassium hydroxide for oxide polishing) can be supplied to the surface of polishing pad 30 by a slurry supply port or combined slurry/rinse arm 39. If polishing pad 30 is a standard pad, slurry 38 can also include abrasive particles (e.g., silicon dioxide for oxide polishing). A clear window 36 is included in polishing pad 30 and is positioned such that it passes beneath substrate 10 during a portion of the platen's rotation, regardless of the translational position of the carrier head.

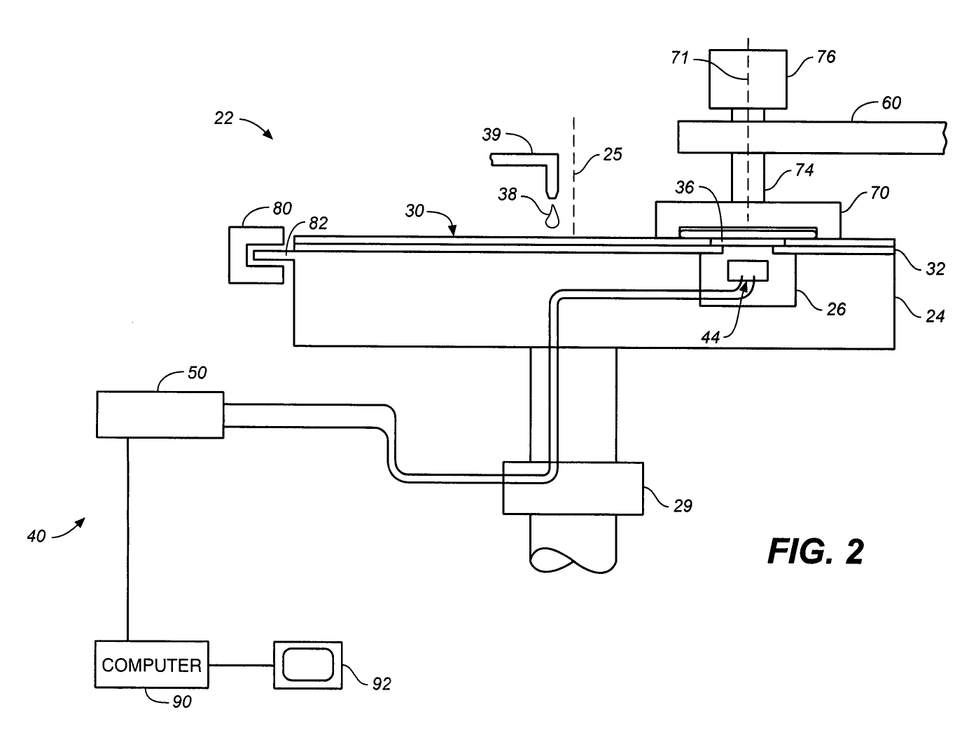

FIG. 2 shows a cross-sectional view of a polishing station 22. In operation, the platen 24 is rotated about its central axis 25, and the carrier head is rotated about its central axis 71 and translated laterally across the surface of the polishing pad 30. CMP apparatus 20 can also include a position sensor 80, such as an optical interrupter, to sense when a recess 26 in platen 24 is beneath substrate 10. For example, the optical interrupter could be mounted at a fixed point opposite carrier head 70. A flag 82 may be attached to the periphery of platen 24. The point of attachment and length of flag 82 is selected so that it interrupts the optical signal of sensor 80 while recess 26 sweeps beneath substrate 10. Alternately, the CMP apparatus can include an encoder to determine the angular position of the platen.

An imaging device 44 (e.g., a charge-coupled device (CCD) array) can be positioned in recess 26 and can be connected to power and interface circuitry 50. The imaging device 44 is located below clear window 36 of polishing pad 30 and sweeps beneath substrate 10 with each rotation of platen 24. In some implementations, multiple imaging devices are placed in recess 26, and a beam splitter (not shown) can also be placed in recess 26 to provide an image of the substrate to the multiple imaging devices. Circuitry 50 can be located outside of platen 24 and can be coupled to the components in the platen through a rotary electrical union 29.

A computer 90 can receive information from circuitry 50 and/or directly from imaging device 44, and can be programmed to execute the methods described below. Output from computer 90 can be displayed on an output device 92 during polishing to permit a user to visually monitor the progress of the polishing operation.

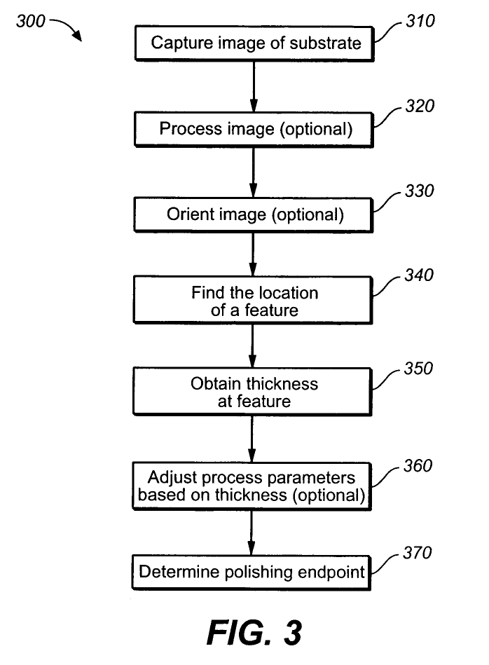

As shown in FIG. 3, a process 300 determines an endpoint for a polishing process using an image of a substrate that is being polished. Process 300 can be used when polishing many types of materials—for example, when polishing a material that is highly reflective for many wavelengths of light (e.g., a metal) or when polishing a material that is transparent or semi-transparent for many wavelengths of light (e.g., an oxide or dielectric). All steps in process 300 can be performed in-situ (e.g., while the substrate is in contact with a polishing pad). In order to measure the thickness of a substrate or a layer on the substrate, an imaging device is used to capture an image of the substrate (step 310). The imaging device can be located in a recess in the platen of a CMP machine and can capture the image through a clear window in the polishing pad. A source of white, colored, or ultraviolet light can also be placed in the recess to illuminate the substrate. During polishing, the platen and a carrier head that holds the substrate typically rotate relative to each other. The rotation causes the window in the polishing pad to sweep under the substrate once per rotation. During each sweep, the imaging device can capture one or more images of the substrate. If multiple images are captured, the multiple images can be combined to form a de-noised image. It can be useful for an image to contain at least one entire die that is included on the substrate in order that a feature in the die can be located, so the image typically includes an area of the substrate that is approximately 4 mm² or larger.

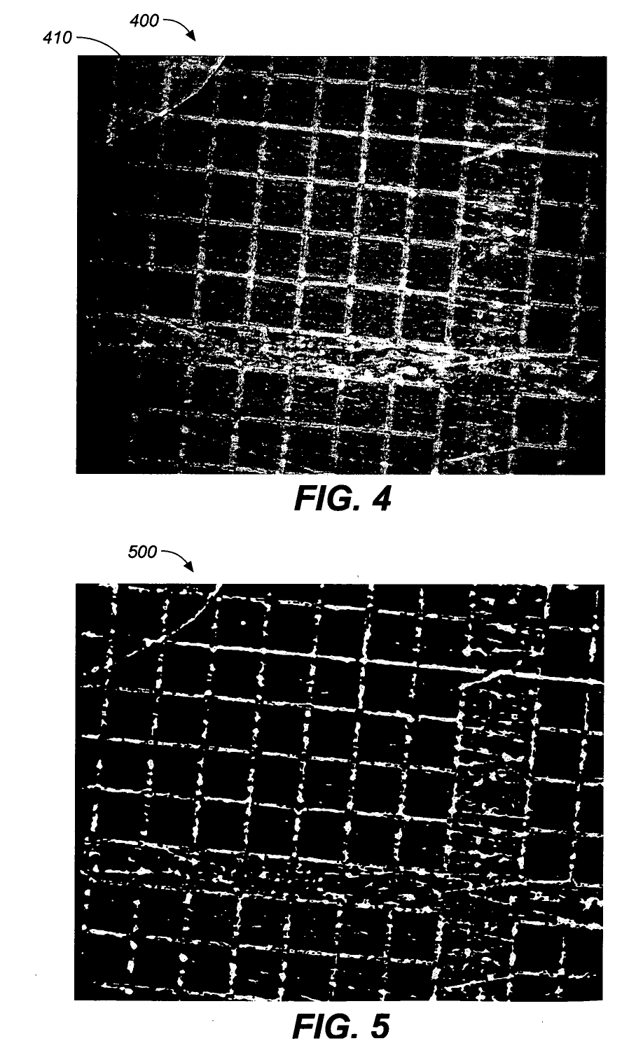

FIG. 4 shows an image 400 of a substrate. While the image 400 is shown in black and white, the image obtained in step 310 of process 300 typically includes information for multiple wavelengths of light (e.g., wavelengths corresponding to visible light, e.g., red, green, and blue light). The wavelengths at which image information is obtained can be selected (e.g., by adding filters to a CCD imaging device) to aid pattern recognition and/or thickness measurement, both of which are discussed below. A wavelength whose intensity does not change substantially as a thickness of a substrate layer changes can be used for pattern recognition. A wavelength whose intensity varies strongly as the thickness of the substrate layer changes can be used for thickness measurement.

Returning to FIG. 3, applying image processing (e.g., sharpening, de-noising, or edge finding) to the image of the substrate (step 320) is useful, though optional. Polishing slurry or deionized water that is between the substrate and the window (e.g., water 410 in FIG. 4) can make the image of the substrate less distinct. Sharpening the image can make features on the substrate more distinct in the image for later steps of process 300. Edge finding can be used to find scribe lines and borders of dies in the image. In FIG. 5, de-noising and edge-finding algorithms have been applied to the image 400 from FIG. 4 to create image 500.

Returning to FIG. 3, if the orientation of the substrate in the image is unknown, the image can be oriented (step 330). One method of orienting the image is to:
1. Average intensity values of the image along a set of parallel lines across the image such that each line has an associated average intensity value.
2. Compute the standard deviation of the average intensity values.
3. Rotate the image slightly and perform steps 1 and 2 again.
   The rotation in step 3 continues until the image has been rotated by 180°, and the angle of rotation that yields the largest standard deviation is used to orient the image. The intensities of multiple wavelengths in the image (corresponding, for example, to red, green, and blue) can be summed separately, so there can be multiple average intensity values associated with each line.

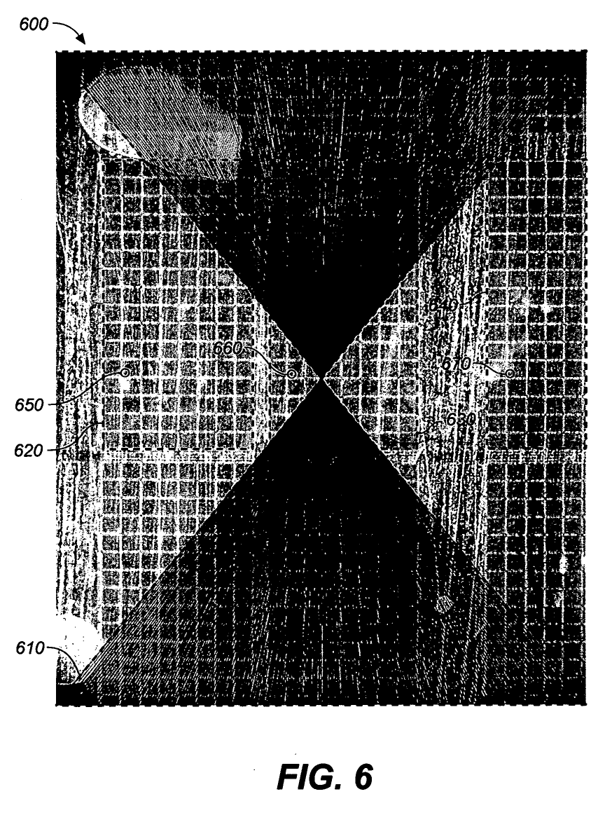

FIG. 6 shows an image 600 with a set of lines 610 overlaid. The set of lines 610 is not part of the image, but has been added to show a set of possible angles of rotation for use in orienting the image 600. As discussed above, an image typically is rotated by 180° during orientation, so the set of lines 610 shows a subset of all of the angles of rotation used to orient image 600. The angle of rotation that yields the largest standard deviation will align dies in the image along an axis defined by the parallel lines because of the contrast between the dies (e.g., dies 620, 630, and 640 in FIG. 6) and the open spaces (e.g., scribe lines) between the dies.

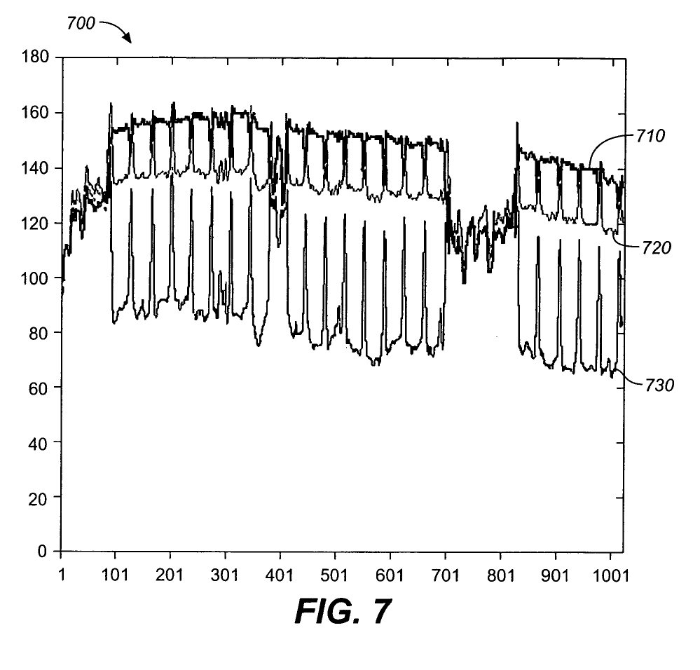

Returning to FIG. 3, the locations of one or more features on the substrate are found in the image (step 340). The features can be located by applying a pattern-recognition algorithm to the image using information from one or more of the wavelengths of light included in the image. FIG. 7 shows graphs 710, 720, and 730 of the image intensity versus location along a line through the image for three different wavelengths. One or more of graphs 710-730 can be used for pattern recognition. The image used to locate features on the substrate in step 340 can be the original image (that is, the image from step 310) rather than the processed image. The features to locate typically are selected by a user and can be selected based on useful properties of the features. For example, it is useful to select features at which intensity information in the image is strongly dependent on the thickness of the substrate layer. One such feature that typically can be used is an open area without structures (e.g., a contact pad area). The features can be located inside or outside of dies included on the substrate.

The thickness of the substrate layer can be obtained for each location (step 350) by examining the data in the image. The intensities of the various wavelengths of light in the image map to a specific thickness of the substrate layer, so thicknesses can be obtained for the locations by examining the intensities at the locations. The thickness of the substrate layer at a given location can be obtained from a single wavelength whose intensity is strongly dependent on the thickness. Alternatively, the intensities of several wavelengths can be monitored and used to obtain the thickness. In one implementation, interferometry is used to obtain the thickness. The process 300 optionally can adjust process parameters for the polishing (step 360) based on the thickness. For example, if the substrate is being held with a carrier head that allows pressures in multiple zones to be controlled independently, the pressures can be adjusted based on the thickness. The process 300 also uses the thickness to determine a polishing endpoint (step 370). Polishing can be terminated when the thickness of the substrate layer at a location reaches a threshold value, or when a feature is exposed. Thicknesses at multiple locations on the substrate can be averaged or otherwise used to determine the polishing endpoint. In one implementation, a features is fabricated between dies (e.g., on a scribe line) specifically for the purpose of endpoint determination.

The thickness of the substrate layer can be monitored at the same location in different dies or open spaces within a single sweep of the window under the substrate. That is, the sequence of measurements from a single sweep of the sensor across the substrate may generated from measurements at the same location (e.g., corresponding to a particular feature) in different dies or open spaces across the substrate. For example, in FIG. 6, the thickness of the substrate layer can be monitored at locations 650, 660, and 670 in dies 620, 630, and 640, respectively.

Similarly, the thickness of the substrate layer can be monitored at the same location in different dies or open spaces over multiple sweeps of the window under the substrate. That is, the same portion of the substrate may not be visible during subsequent sweeps of the window under the substrate, so thicknesses can by obtained at the same location (e.g., corresponding to a particular feature) in different dies or open spaces that are substantially identical. Obtaining successive thicknesses from different dies or open spaces at a same radial position on the substrate can be useful to obtain consistent results from sweep to sweep.

In one implementation, a beam splitter is used to provide an image of the substrate to multiple imaging devices. The images produced by the imaging devices can be combined into a single image for processing or can be processed individually. Each imaging device can be optimized to generate an image of a particular wavelength of light.

The clear window in the polishing pad, through which the images are captured, can be made from quartz and/or include a polymer top layer. Nozzles can be positioned to flush polishing slurry off of the window before the window sweeps under the substrate in order to obtain a clearer image of the substrate.

A number of embodiments of the invention have been described. Nevertheless, it will be understood that various modifications may be made without departing from the spirit and scope of the invention. Accordingly, other embodiments are within the scope of the following claims.

What is claimed is:

1. A computer-implemented method, comprising:
capturing, in-situ, an image of a portion of a substrate, the image including optical information that depends on a thickness of a substrate layer;
finding in the image a location on the substrate; and
determining a process endpoint using a portion of the optical information that corresponds to the location.

2. The computer-implemented method of claim 1, wherein:
finding the location includes at least one of applying a pattern-recognition algorithm to the image, sharpening the image, and orienting the image.

3. The computer-implemented method of claim 2, wherein:
orienting the image includes calculating standard deviations of averaged intensity values in the image.

4. The computer-implemented method of claim 1, wherein:
determining a process endpoint using a portion of the optical information includes at least one of analyzing a spectrum of the image, using interferometry, and averaging a plurality of thicknesses at multiple locations in the image.

5. The computer-implemented method of claim 1, further comprising:
obtaining, in-situ, the thickness of the substrate layer at the location using the portion of the optical information that corresponds to the location, wherein the obtained thickness is used to determine the process endpoint.

6. The computer-implemented method of claim 5, further comprising:
repeating the steps of capturing an image, finding a location, and obtaining the thickness to monitor a change in thickness over time.

7. The computer-implemented method of claim 6, wherein:
the substrate includes a plurality of dies;
finding the location includes finding the location relative to a first die in the plurality of dies; and
successive thicknesses are obtained from a same location in different dies in the plurality of dies.

8. The computer-implemented method of claim 1, wherein:
an area of the portion of the substrate captured in the image is greater than 4 mm².

9. The computer-implemented method of claim 1, further comprising:
capturing an additional image of the portion of the substrate, the additional image including additional optical information that depends on the thickness of the substrate layer, wherein determining the process endpoint includes determining the process endpoint using the additional optical information.

10. The computer-implemented method of claim 9, wherein:
the optical information that depends on the thickness of the substrate layer includes optical information centered at a first wavelength; and
the additional optical information that depends on the thickness of the substrate layer includes optical information centered at a second wavelength, the first wavelength being different from the second wavelength.

11. The computer-implemented method of claim 1, further comprising:
cleaning an imaging window through which the image is captured.

12. The computer-implemented method of claim 1, further comprising:
adjusting a polishing parameter using the optical information, the polishing parameter affecting a rate at which the substrate is polished.

13. The computer-implemented method of claim 1, wherein:
the substrate includes a plurality of dies; and
the portion of the substrate included in the image includes substantially an entire die in the plurality of dies.

14. The computer-implemented method of claim 1, wherein the substrate includes a plurality of dies, the method further comprising:
capturing, in-situ, a sequence of images of the substrate, at least some of the sequence of images including images of different dies in the plurality of dies; and
finding in the images of the different dies a common location in the different dies, wherein determining the process endpoint using a portion of the optical information includes using optical information that corresponds to the common location in the different dies.

15. A computer program product, tangibly embodied on an information carrier, comprising instructions operable to cause a data processing apparatus to:
capture, in-situ, an image of a portion of a substrate, the image including optical information that depends on a thickness of a substrate layer;
find in the image a location on the substrate; and
determine a process endpoint using a portion of the optical information that corresponds to the location.

16. The computer program product of claim 15, wherein:
the instructions operable to find the location include instructions operable to perform at least one of applying a pattern-recognition algorithm to the image, sharpening the image, and orienting the image.

17. The computer program product of claim 16, wherein:
the instructions operable to orient the image include instructions operable to calculate standard deviations of averaged intensity values in the image.

18. The computer program product of claim 15, wherein:
the instructions operable to determine the process endpoint include instructions operable to perform at least one of analyzing a spectrum of the image, using interferometry, and averaging a plurality of thicknesses at multiple locations in the image.

19. The computer program product of claim 15, further comprising instructions operable to:
obtain, in-situ, the thickness of the substrate layer at the location using the portion of the optical information that corresponds to the location, wherein the obtained thickness is used to determine the process endpoint.

20. The computer program product of claim 19, further comprising instructions operable to:
repeat the instructions operable to capture an image, find a location, and obtain the thickness to monitor a change in thickness over time.

21. The computer program product of claim 20, wherein:
the substrate includes a plurality of dies;
finding the location includes finding the location relative to a first die in the plurality of dies; and
successive thicknesses are obtained from a same location in different dies in the plurality of dies.

22. The computer program product of claim 15, wherein:
an area of the portion of the substrate captured in the image is greater than 4 mm².

23. The computer program product of claim 15, further comprising instructions operable to:
capture an additional image of the portion of the substrate, the additional image including additional optical information that depends on the thickness of the substrate layer, wherein the instructions operable to determine the process endpoint include instructions operable to determine the process endpoint using the additional optical information.

24. The computer program product of claim 23, wherein:
the optical information that depends on the thickness of the substrate layer includes optical information centered at a first wavelength; and
the additional optical information that depends on a thickness of the substrate layer includes optical information centered at a second wavelength, the first wavelength being different from the second wavelength.

25. The computer program product of claim 15, further comprising instructions operable to:
cause an imaging window through which the image is captured to be cleaned.

26. The computer program product of claim 15, further comprising instructions operable to:
adjust a polishing parameter using the optical information, the polishing parameter affecting a rate at which the substrate is polished.

27. The computer program product of claim 15, wherein:
the substrate includes a plurality of dies; and
the portion of the substrate included in the image includes substantially an entire die in the plurality of dies.

28. The computer program product of claim 15, wherein the substrate includes a plurality of dies, the computer program product further comprising instructions operable to:
capture, in-situ, a sequence of images of the substrate, at least some of the sequence of images including images of different dies in the plurality of dies; and
find in the images of the different dies a common location in the different dies, wherein the instructions operable to determine the process endpoint using a portion of the optical information include instructions operable to use optical information that corresponds to the common location in the different dies.
